(19) United States
(12) Patent Application Publication
(10) Pub. No.: US 2007/0200118 A1
(43) Pub. Date: Aug. 30, 2007

(54) LED LIGHT CONFINEMENT ELEMENT

(76) Inventor: Kenneth A. Epstein, St. Paul, MN (US)

Correspondence Address: 3M INNOVATIVE PROPERTIES COMPANY, PO BOX 33427, ST. PAUL, MN, 55133-3427, US

(21) Appl. No.: 11/275,289

(22) Filed: Dec. 21, 2005

(51) Int. Cl. H01L 33/00

(52) U.S. Cl. 257/79

(57) ABSTRACT

An optical assembly includes a reflective layer, an optical element covering at least a portion of the reflective layer, and an LED having a light-emitting axis and disposed to emit light between the optical element and the reflective layer. The optical element has a rotationally symmetric funnel-shaped recess in substantial registration with the light-emitting axis and the optical element also has an overall outer shape that is non-rotationally symmetric. An optical array of these assemblies and backlight displays including these assemblies are also disclosed.

### BACKGROUND

The present disclosure relates to LED light confinement elements. More specifically the present disclosure relates to LED light confinement elements that produce a non-rotationally symmetric light pattern about a light-emitting axis.

LED arrays can be constructed using packaged LEDs that have a polymer encapsulant formed over an LED die mounted in a reflector cup. Much of the light generated within the LED die is trapped due to total internal reflection at the die surface. Of the light emitted from the packaged LED, much is emitted out of the polymer encapsulant directly above the LED die along a light-emitting axis of symmetry.

### SUMMARY

The present application discloses, inter alia, LED light confinement elements, including such elements that produce a non-rotationally symmetric light pattern about a light-emitting axis of an LED. The light-emitting axis may correspond, for example, to a direction of maximum flux or brightness of the LED, or to an axis of symmetry of the LED or one of its components, such as the LED die or LED encapsulant (if present), or to an axis of symmetry of the light distribution of the LED, or to another selected direction associated with the LED.

Optical assemblies are disclosed that include a light emitting diode (LED) having a light-emitting axis, a reflective layer situated adjacent the LED and about the light-emitting axis, and an optical element disposed over the LED and reflective layer. The optical element has a funnel-shaped recess that is rotationally symmetric about the light-emitting axis. The optical element however has an overall shape that is non-rotationally symmetric, such that it emits light generated by the LED in a non-rotationally symmetric pattern about the light-emitting axis.

Optical assemblies are disclosed that include an array of light emitting diodes (LEDs), the array of LEDs are disposed adjacent a reflective layer and each LED has a light-emitting axis. The array of LEDs emits light. An optical film is disposed over the array of LEDs and the reflective layer. The optical film has a plurality of optical elements disposed over the LEDs and the reflective layer. At least selected optical elements have a funnel-shaped recess disposed about selected light-emitting axes. Each funnel-shaped recess has a rotationally symmetric shape about the selected light-emitting axis. Each selected optical element emits a non-rotationally symmetric light pattern about the light-emitting axis.

In a further aspect of the disclosure, a backlight display assembly includes a light emitting diode (LED) having a light-emitting axis and emitting light, a reflective layer is situated adjacent the LED and about the light-emitting axis, an optical element is disposed over the LED and reflective layer, and an optical display element is disposed above the optical element for emitting the light. The optical element has a funnel-shaped recess disposed about the light-emitting axis. The funnel-shaped recess has a rotationally symmetric shape about the light-emitting axis. The optical element emits a non-rotationally symmetric light pattern about the light-emitting axis.

These and other aspects of the present application will be apparent from the detailed description below. In no event, however, should the above summaries be construed as limitations on the claimed subject matter, which subject matter is defined solely by the attached claims, as may be amended during prosecution.

### BRIEF DESCRIPTION OF THE DRAWINGS

The disclosure may be more completely understood in consideration of the following detailed description in connection with the accompanying drawings, in which:

FIG. 1 is a side elevation schematic sectional view of an illustrative optical assembly;

FIGS. 2-5 are schematic top views of illustrative embodiments of optical assemblies;

FIG. 6 is a side elevation schematic sectional view of an illustrative optical assembly array;

FIG. 7a is a schematic perspective view of an LED light source;

FIG. 7b is a is a schematic sectional view of an alternative LED light source; and

FIG. 8 is a side elevation schematic sectional view of an illustrative optical assembly.

While the invention is amenable to various modifications and alternative forms, specifics thereof have been shown by way of example in the drawings and will be described in detail. It should be understood, however, that the intention is not to limit the invention to the particular embodiments described. On the contrary, the intention is to cover all modifications, equivalents, and alternatives falling within the spirit and scope of the invention.

### DETAILED DESCRIPTION

In backlight design, it is sometimes desirable to receive light from multiple compact sources and to spread out the light across a surface area (e.g., an LCD backlight illuminated directly with CCFL tubes or LEDs. The basic luminaire can include a cavity in which light propagates and reflects and eventually is extracted toward the viewer. Long light paths within the cavity are desirable to permit adequate spreading such that brightness and color uniformity across the backlight area is achieved. An additional consideration is the thinness of the backlight.

One method to extend light paths is to confine light to a polymer lightguide, which may suffer loss if the polymer is absorptive. Alternatively, light sources can be positioned to emit light into a hollow cavity bounded by a partially transmitting sheet and a fully reflective sheet. In this case, the light sources are chosen to emit the majority of light into angles close to the plane of the cavity so that light can spread freely with few reflections.

For the following defined terms, these definitions shall be applied, unless a different definition is given in the claims or elsewhere in this specification.

The recitation of numerical ranges by endpoints includes all numbers subsumed within that range (e.g. 1 to 5 includes 1, 1.5, 2, 2.75, 3, 3.80, 4, and 5).

As used in this specification and the appended claims, the singular forms “a”, “an”, and “the” include plural referents unless the content clearly dictates otherwise. Thus, for example, reference to a composition containing “a layer” includes of two or more layers. As used in this specification and the appended claims, the term “or” is generally employed in its sense including “and/or” unless the content clearly dictates otherwise.

Unless otherwise indicated, all numbers expressing quantities, measurement of properties and so forth used in the specification and claims are to be understood as being modified in all instances by the term “about.” Accordingly, unless indicated to the contrary, the numerical parameters set forth in the specification and claims are approximations that can vary depending upon the desired properties sought to be obtained by those skilled in the art utilizing the teachings of the present invention. At the very least, and not as an attempt to limit the application of the doctrine of equivalents to the scope of the claims, each numerical parameter should at least be construed in light of the number of reported significant digits and by applying ordinary rounding techniques. Notwithstanding that the numerical ranges and parameters setting forth the broad scope of the invention are approximations, the numerical values set forth in the specific examples are reported as precisely as possible. Any numerical value, however, inherently contains certain errors necessarily resulting from the standard deviations found in their respective testing measurements.

The term “LED” is used herein to refer to a diode that emits light, whether visible, ultraviolet, or infrared. It includes incoherent encased or encapsulated semiconductor devices marketed as “LEDs”, whether of the conventional or super radiant variety. If the LED emits non-visible light such as ultraviolet light, and in some cases where it emits visible light, it can be packaged to include a phosphor (or it may illuminate a remotely disposed phosphor) to convert short wavelength light to longer wavelength visible light, in some cases yielding a device that emits white light. An “LED die” is an LED in its most basic form, i.e., in the form of an individual component or chip made by semiconductor processing procedures. For example, the LED die is ordinarily formed from a combination of one or more Group III elements and of one or more Group V elements (III-V semiconductor). Examples of suitable III-V semiconductor materials include nitrides, such as gallium nitride, and phosphides, such as indium gallium phosphide. Other types of III-V materials can be used also, as might inorganic materials from other groups of the periodic table. The component or chip can include electrical contacts suitable for application of power to energize the device. Examples include wire bonding, tape automated bonding (TAB), or flip-chip bonding. The individual layers and other functional elements of the component or chip are typically formed on the wafer scale, and the finished wafer can then be diced into individual piece parts to yield a multiplicity of LED dies. The LED die may be configured for surface mount, chip-on-board, or other known mounting configurations. Some packaged LEDs are made by forming a polymer encapsulant over an LED die and an associated reflector cup. The LED die has a quasi-Lambertian emission pattern and much of the light generated within the LED die is trapped due to total internal reflection at the die surface or emitted out of the polymer encapsulant directly above the LED die.

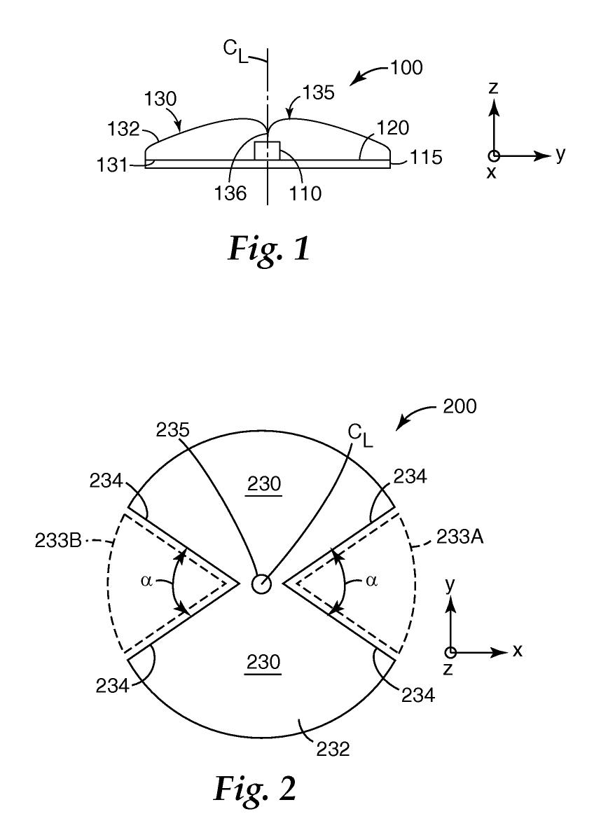

FIG. 1 is a side elevation schematic cross-sectional view of an illustrative optical assembly 100. The optical assembly 100 includes a light emitting diode (LED) 110 having a light-emitting axis C_{L} extending along a z-axis, a reflective layer 120 situated adjacent the LED 110, and an optical element 130 disposed over the LED 110 and reflective layer 120. The optical element 130 has a funnel-shaped recess 135 disposed about the light-emitting axis C_{L}. Preferably, the funnel-shaped recess 135 has a rotationally symmetric shape about the light-emitting axis C_{L}, yet the optical element 130 emits a non-rotationally symmetric light pattern about the light-emitting axis C_{L} due to a non-rotationally symmetric overall or outer shape, as explained further below.

The reflective layer 120 can be provided on a substrate 115. The reflective layer 120 directs light emitted from the LED 110 back into the optical element 130. The substrate 115 can be formed of any useful material. In some embodiments, the substrate 115 is formed of a metal, ceramic, or polymer. Conductors may be provided on different layers for carrying electrical current to and from the LED 110. For example, conductors may be provided on the substrate 115. The conductors may take the form of metallic traces, for example formed from copper.

The LED 110 emits light over a wide range of angles. The optical element 130 redirects this light in directions (e.g. along the x-axis and/or y-axis) that are generally parallel to the reflective layer 120 surface and/or generally perpendicular to the light-emitting axis C_{L} (i.e., the z-axis), that is, directions having a high polar angle relative to the light-emitting axis. The optical assembly 100 can thus be described as a “side-emitting” LED assembly.

The optical element 130 can be formed of any useful material. In many embodiments, the optical element 130 is a polymeric material, transparent to the light emitted by the LED 110. For example, the optical element 130 can be formed from a polycarbonate, polyester, polyurethane, polyacrylate, and the like.

Optical element 130 need not have parallel surfaces. As shown in FIG. 1, the optical element 130 has a lower or first surface 131 on or adjacent to and substantially parallel to the reflective layer 120; and an upper or second surface 132 non-parallel to the reflective layer 120. The first surface 131 and the second surface 132 cooperate to form a wedge shape profile so that LED emitted light reflects between the reflective layer 120 and the upper surface 132 until the emitted or reflected light is incident on the upper surface 132 at an angle of incidence less than the critical angle. Once the emitted or reflected light is incident on the upper surface 132 at an angle of incidence less than the critical angle, this light is transmitted through the upper surface 132 and/or outer edges. Such transmitted light can be referred to as side-emitted light because of its relatively high polar angle with respect to the light-emitting axis C_{L}. The reader will understand that the polar angle at which the brightness or intensity of light emitted by the assembly 100 becomes maximum can be readily tailored by appropriate selection of the wedge angle between surface 131 and the outer region (beyond recess 135) of upper surface 132.

Upper surface 132 includes a funnel-shaped recess 135 having a rotationally symmetric shape about the light-emitting axis C_{L}, the recess being disposed above and in substantial registration with the LED 110. LED emitted light is internally reflected at the recess 135 surface and directed away from the light-emitting axis C_{L}. The recess 135 preferably terminates at a sharp point or cusp 136 to minimize the transmission of on-axis LED light out of the optical element 130, or to maximize side-emitted light out of the optical element. If some on-axis LED light is desired, the cusp can be replaced with a small flat disk-shaped surface parallel to surface 131, where the diameter of the disk-shaped surface is selected to control the amount of LED light emitted out of the optical element along light-emitting axis C_{L}. The recess 135 can be a surface of rotation defined by a curve revolved about the light-emitting axis C_{L}, where the curve is calculated to totally internally reflect the LED emitted light within the central region of the optical element 130, i.e., in the vicinity of cusp 136.

Optical assemblies described herein can provide a compact light confinement structure having low axial intensity (is side emitting) and can be formed in continuous sheet structures, as described below. These compact light confinement structures can emit light at high polar angles (measured with respect to the light-emitting or z-axis) and selected azimuth angles (measured in the x-y plane relative to a reference direction such as the x- or y-axis). The emitted light is non-rotationally symmetric about the z- or light-emitting axis because of a non-rotational symmetry in the overall or outer shape of the light confinement structure.

FIG. 2 is a schematic top view of an illustrative embodiment of an optical assembly 200. The optical assembly 200 includes a light confinement or optical element 230 having a light-emitting axis C_{L} and a funnel-shaped recess 235 disposed at or near the center of the optical element 230. An LED (not shown) is disposed below the recess 235 and along the light-emitting axis C_{L} as described in relation to FIG. 1 above. The recess 235 is formed within an upper surface 232 of the optical element 230.

The illustrated optical element 230 has a generally circular shape with one or more “notch” or “pie” shaped sectors 233A and 233B removed from the generally circular shape. Thus, the optical element 230 described herein has a notched shape. While two notch-shaped sectors 233A and 233B are shown removed from the optical element 230, it is understood that only one notch-shaped sector could be missing from the optical element 230 or the optical element 230 could have 3, 4, 5, 6, 7 or more notch-shaped sectors removed in a uniform or random fashion. The notch-shaped sectors 233A and 233B can be defined by a sector extending adjacent the funnel-shaped recess 235 having any useful angle α. In exemplary embodiments, the angle α is in a range from 10 to 120 degrees, or 60 to 120 degrees, or 60 degrees, 90 degrees, or 120 degrees. If two or more notch-shaped sectors are missing from the optical element 230, each such sector can have the same or different angle α. The optical element 230 preferentially emits light along the x-y plane outwardly from the upper surface 232 and/or outer edges of the optical element, but emits little or substantially no light outwardly from the notch-shaped sectors 233A and 233B. Thus, light is emitted from the optical element 230 in a non-rotationally symmetric fashion about the light-emitting axis C_{L}. The sectors 233A and 233B are defined by linear side walls 234, however the side walls 234 may be curved, as desired.

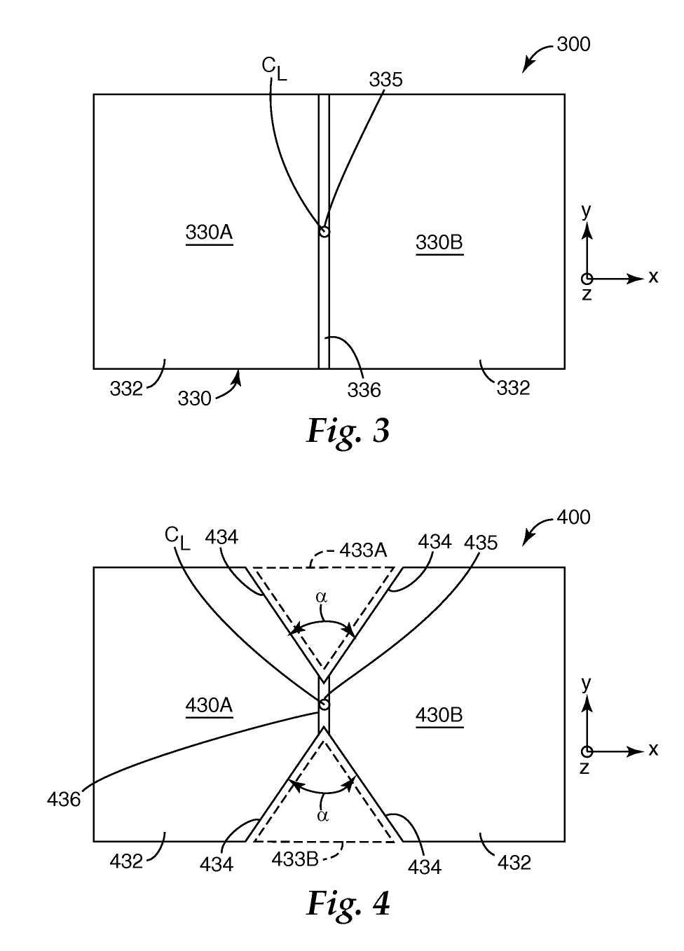

FIG. 3 is a schematic top view of an illustrative embodiment of a rectangular optical assembly 300. The optical assembly 300 includes a light confinement or optical element 330 having a light-emitting axis C_{L} and a funnel-shaped recess 335 disposed at or near the center of the optical element 330. An LED (not shown) is disposed below the recess 335 and along the light-emitting axis C_{L} as described in relation to FIG. 1 above. The recess 335 is formed within an upper surface 332 of the optical element 330. The optical element 330 includes a planar portion 336 that is parallel or substantially parallel to the x-y plane and tapering portions 330A and 330B extending from the planar portion 336.

The tapering portions 330A and 330B have a maximum thickness adjacent the planar portion 336 and taper to a decreasing thickness as the distance from the planar portion 336 increases. The optical element 330 preferentially emits light along the x-y plane outwardly from the upper surface 332 and/or edges of the optical element 330. Thus, light generated by the LED is emitted from the optical element 330 in a non-rotationally symmetric fashion about the light-emitting axis C_{L}. The tapering portions 330A and 330B may also be subdivided into additional planar surfaces that are not parallel to each other, but meet at the axis C_{L} and slope toward the reference plane 336. For example, surface 332 could approximate a four-sided pyramid.

FIG. 4 is a schematic top view of another illustrative embodiment of a generally rectangular optical assembly 400. The optical assembly 400 includes a light confinement or optical element 430 having a light-emitting axis C_{L} and a funnel-shaped recess 435 disposed at or near the center of the optical element 430. An LED (not shown) is disposed below the funnel-shaped recess 435 and along the light-emitting axis C_{L} as described in relation to FIG. 1 above. The recess 435 is formed within an upper surface 432 of the optical element 430. The optical element 430 includes a planar portion 436 that is parallel or substantially parallel to the x-y plane and tapering portions 430A and 430B extending from the planar portion 436. The tapering portions 430A and 430B have a maximum thickness adjacent the planar portion 436 and taper to a decreasing thickness as the distance (in the ±x-axis directions) from the planar portion 436 increases.

The illustrated optical element 430 has a generally rectangular shape with one or more notch- or triangle-shaped sectors 433A and 433B removed from the generally rectangular shape. Thus, the optical element 430 described herein has a notched shape. While two triangle-shaped sectors 433A and 433B are shown removed from the optical element 430, it is understood that only one triangle-shaped sector could be missing from the optical element 430 or the optical element 430 could have 3, 4, 5, 6, 7 or more triangle-shaped sectors removed in a uniform or random fashion. The triangle-shaped sectors 433A and 433B can be defined by a sector extending adjacent the funnel-shaped recess 435 having any useful angle α. In exemplary embodiments, the angle α is in a range from 10 to 120 degrees, or 60 to 120 degrees, or 60 degrees, 90 degrees, or 120 degrees. If two or more triangle-shaped sectors are missing from the optical element 430, each such sector can have the same or different angle α. The optical element 430 preferentially emits light along the x-y plane outwardly from the upper surface 432 and/or outer edges of the optical element, but emits little or substantially no light outwardly from the triangle-shaped sectors 433A and 433B. Thus, light is emitted from the optical element 430 in a non-rotationally symmetric fashion about the light-emitting axis C_{L}. The triangle-shaped sectors 433A and 433B are defined by linear side walls 434, however the side walls 434 may be curved, as desired.

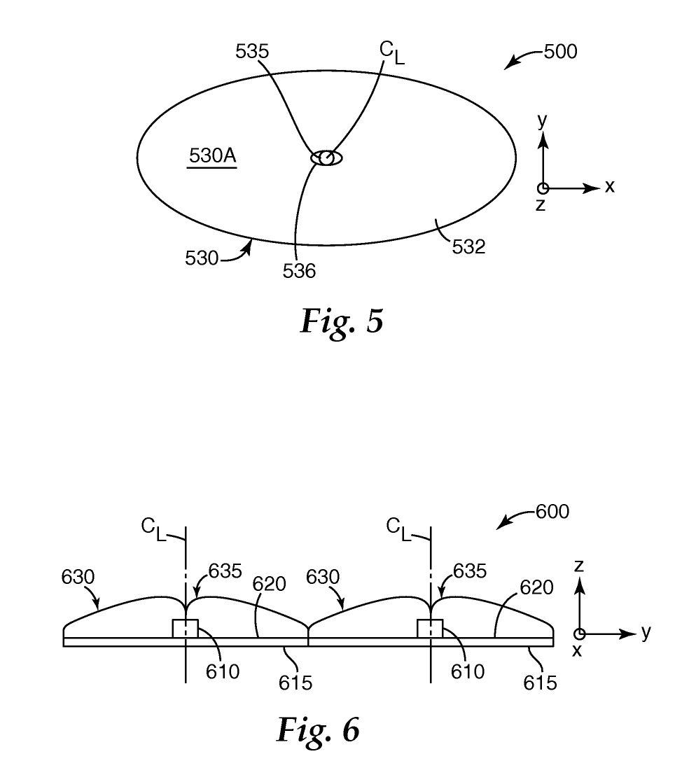

FIG. 5 is a schematic top view of an illustrative embodiment of an elliptical optical assembly 500. The optical assembly 500 includes a light confinement or optical element 530 having a light-emitting axis C_{L} and a funnel-shaped recess 535 disposed at or near the center of the optical element 530. An LED (not shown) is disposed below the recess 535 and along the light-emitting axis C_{L} as described in relation to FIG. 1 above. The recess 535 is formed within an upper surface 532 of the optical element 530. The optical element 530 includes a planar portion 536 that is substantially parallel to the x-y plane and tapering portion 530A extending from the planar portion 536. The tapering portion 530A has a maximum thickness adjacent the planar portion 536 and taper to a decreasing thickness as the distance from planar portion 536 increases (in both the ±x-directions and the ±y-directions). The optical element 530 can have any elliptical shape, which can be characterized by the ratio of the semi-major and semi-minor axes of the ellipse. In some embodiments, this ratio is 1.5, 2, or 3. The optical element 530 preferentially emits light along the ±x-directions outwardly from the upper surface 532 and/or edge of the optical element 530. Thus, light is emitted from the optical element 530 in a non-rotationally symmetric fashion about the light-emitting axis C_{L}.

FIG. 6 is a side elevation schematic cross-sectional view of an illustrative optical assembly array 600. Optical elements described in FIG. 1 can be formed into a continuous sheet by any number of conventional methods. The optical elements 630 can be disposed on the continuous sheet in any uniform or non-uniform fashion to form an array of optical elements. This array of optical elements can then be disposed over a corresponding array of LEDs such that at least selected optical elements are in registration with at least selected LEDs. While FIG. 6 illustrates an array of two optical elements 630, it is understood that the array can include any useful number of optical elements disposed on the x-axis and/or y-axis. In some embodiments, the array includes from 2 to 1000 optical elements, or from 5 to 5000 optical elements, or from 50 to 500 optical elements.

The optical assembly array 600 includes a plurality of LEDs 610 each having a light-emitting axis C_{L} extending along a z-axis, a reflective layer 620 situated adjacent the LEDs 610, and a plurality of optical elements 630 disposed over the plurality of LEDs 610 and reflective layer 620. In exemplary embodiments, the optical elements 630 each have a funnel-shaped recess 635 disposed about the light-emitting axis C_{L}. The funnel-shaped recesses 635 preferably have a rotationally symmetric shape about the corresponding light-emitting axis C_{L}, and the optical elements 635 emit a non-rotationally symmetric light pattern about the corresponding light-emitting axis C_{L}. Each optical element 630 can operate in the manner described above.

FIG. 7a is a schematic perspective view of an LED light source useful in any of the embodiments disclosed herein. This light source is an LED die. This LED die can include one or more electrical contact pads, e.g., in the center of the LED die (not shown). A light-emitting axis C_{L} is shown extending through the center of the LED die.

FIG. 7b is a schematic sectional view of an alternative LED light source useful in any of the embodiments disclosed herein. This LED light source includes an encapsulant that surrounds the LED die, reflective cup, and wire bond. Such LED sources are commercially available from a number of manufacturers. A light-emitting axis C_{L} is shown extending through the center of the LED die and encapsulant.

In some embodiments, the optical elements can be combined to form arrays of optical elements. An array of LEDs can be combined with the array of optical elements, where each optical element has a light-emitting axis. Preferably, each optical element has a recess that is substantially aligned with a light-emitting axis of a corresponding LED. In some embodiments, the LEDs can be disposed adjacent a reflective layer. If the LEDs each include an LED die disposed within an encapsulant, the optical elements can be formed individually on each of the encapsulants. Alternatively, the optical elements can be formed in a continuous optical film that extends over some or all of the LEDs in the array.

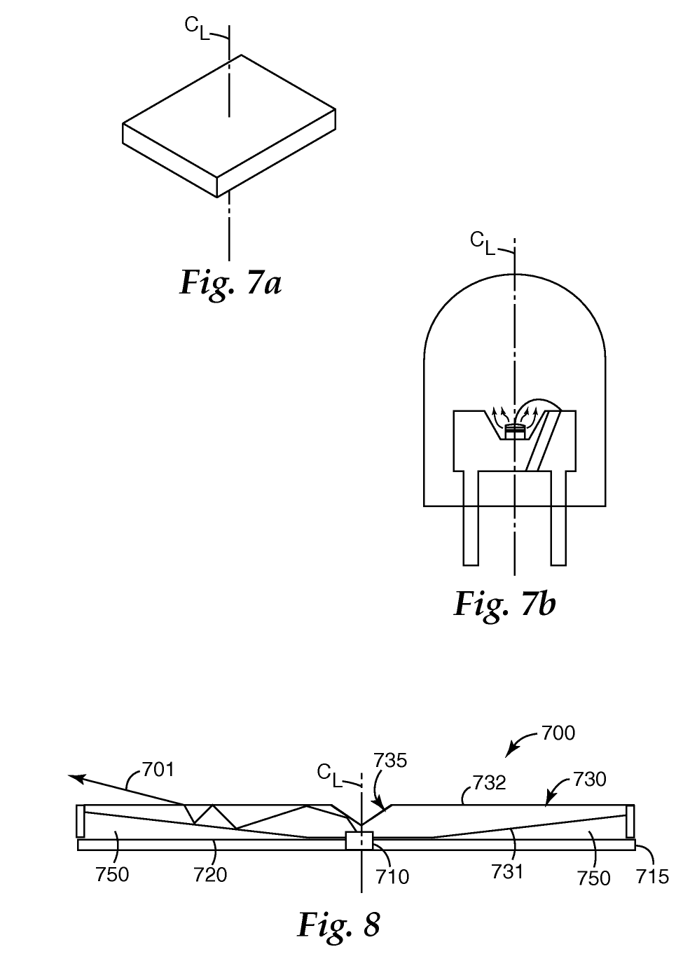

FIG. 8 is a side elevation schematic sectional view of an illustrative optical assembly 700. The optical assembly 700 includes a light emitting diode (LED) 710 having a light-emitting axis C_{L} extending along a z-axis, a reflective layer 720 situated adjacent the LED 710, and an optical element 730 disposed over the LED 710 and reflective layer 720. The optical element 730 has a funnel-shaped recess 735 disposed about the light-emitting axis C_{L}, the recess 735 preferably being rotationally symmetric about such axis and preferably disposed above and in registration with LED 710. An air gap 750 is disposed between the optical element 730 and the reflective layer. The air gap 750 can assist in confining the emitted light within the optical element 730.

The optical element 730 emits a non-rotationally symmetric light pattern about the light-emitting axis C_{L}.

The reflective layer 720 can be provided on a substrate 715. The reflective layer 720 directs light emitted from the LED 710 back into the optical element 730. The substrate 715 can be formed of any useful material, as described above. LED light is emitted from the LED 710 over a wide range of angles. A ray trace 701 is shown originating from the LED 710, reflecting off the recess 735 and the central region of an upper surface 732, then off a lower surface 731 of the optical element 730, until it is emitted from an outer region of the optical element 730. The optical element 730 described herein emits this emitted light in lateral directions generally parallel to the reflective layer 720 surface and/or generally perpendicular to the light-emitting axis C_{L} (along the z-axis). This optical assembly 700 can be described as a “side-emitting” LED assembly.

The optical element 730 can be formed of any useful material, as described above. In this embodiment, the optical element 730 has non-parallel upper and lower surfaces 732 and 731. As shown in FIG. 8, the optical element 730 has a lower or first surface 731 adjacent to and non-parallel with the reflective layer 720; and an upper or second surface 732 that is parallel or substantially parallel to the reflective layer 720. The first surface 731 and the second surface 732 cooperate to form a wedge shape profile so that LED emitted light reflects off the reflective surface and the central region of upper surface 732 until the emitted or reflected light is incident on an outer region of upper surface 732 at an angle of incidence less than the critical angle. Once the emitted or reflected light is incident on the upper surface 732 at an angle of incidence less than the critical angle this light is transmitted through the upper surface 732 and/or outer edges, as emitted light.

The optical assemblies and arrays described herein can be utilized in a variety of flat illumination, display or backlight applications where an optical display element is disposed above the optical element for emitting the light. In some embodiments, the optical display element includes a liquid crystal layer.

The optical assemblies and arrays described herein can be formed by any useful method. In some embodiments, these optical assemblies and arrays are molded. In some embodiments, these optical assemblies and arrays are formed on a web or film of any length.

The present invention should not be considered limited to the particular examples described herein, but rather should be understood to cover all aspects of the invention as fairly set out in the attached claims. Various modifications, equivalent processes, as well as numerous structures to which the present invention can be applicable will be readily apparent to those of skill in the art to which the present invention is directed upon review of the instant specification.

1. An optical assembly, comprising:
a reflective layer;
an optical element covering at least a portion of the reflective layer; and
a light emitting diode (LED) having a light-emitting axis and disposed to emit light between the optical element and the reflective layer;
wherein the optical element has a rotationally symmetric funnel-shaped recess in substantial registration with the light-emitting axis, the optical element having an overall shape that is non-rotationally symmetric.

2. The assembly of claim 1, wherein the optical element has a notched shape.

3. The assembly of claim 1, wherein the optical element has an elliptical shape.

4. The assembly of claim 1, wherein the optical element has a rectangular shape or square shape.

5. The assembly of claim 1, wherein the optical element has a second surface substantially parallel to the reflective layer and a first surface non-parallel with the first surface, and wherein the optical element is tapered and has a maximum thickness at the light-emitting axis.

6. The assembly of claim 1, wherein the optical element has a plurality of notches extending adjacent the funnel-shaped recess, the notches each being characterized by an included angle in a range from 60 to 120 degrees.

7. The assembly of claim 6, wherein the optical element has a general rectangular, square, circular, or elliptical shape.

8. The assembly of claim 5, wherein the funnel-shaped recess is a portion of the second surface of the optical element.

9. The assembly of claim 1, wherein the optical element redirects some LED light emitted initially along the light-emitting axis to directions that are substantially perpendicular to the light-emitting axis.

10. The assembly of claim 1, further comprising an air gap disposed between the reflective layer and the optical element.

11. An optical assembly, comprising:
an array of light emitting diodes (LEDs), the array of LEDs disposed adjacent a reflective layer and each LED having a light-emitting axis; and
an optical film disposed over the array of LEDs and the reflective layer, the optical film having a plurality of optical elements formed therein, at least selected optical elements having a rotationally symmetric funnel-shaped recess in substantial registration with selected light-emitting axes, each selected optical element having a non-rotationally symmetric shape.

12. The assembly of claim 11, wherein the non-rotationally symmetric shape is a notched shape.

13. The assembly of claim 11, wherein the non-rotationally symmetric shape is an elliptical shape.

14. The assembly of claim 11, wherein the selected optical elements are tapered and have a second surface substantially parallel to the reflective layer and a first surface non-parallel with the first surface.

15. The assembly of claim 12, wherein the selected optical elements have at least one notch extending adjacent the respective funnel-shaped recess.

16. The assembly of claim 11, further comprising an air gap disposed between the reflective layer and the optical film.

17. A backlight display assembly, comprising:
a light emitting diode (LED) having a light-emitting axis;
a reflective layer disposed adjacent the LED;
an optical element disposed over the LED and the reflective layer, the optical element having a rotationally symmetric funnel-shaped recess disposed about the light-emitting axis, and the optical element also having a non-rotationally symmetric outer shape; and
an optical display element disposed to receive light directly or indirectly from the optical element.

18. The display of claim 17, wherein the optical display element comprises a liquid crystal layer.

19. The display of claim 17, wherein the LED is one of a plurality of LEDs, and the optical element is one of a plurality of optical elements, each optical elements being disposed over a corresponding LED.

20. The display of claim 17, further comprising an air gap between the reflective layer and the optical element.
